(19) United States
(12) Patent Application Publication
(10) Pub. No.: US 2025/0266286 A1
(43) Pub. Date: Aug. 21, 2025

(54) SUSCEPTOR AND EPITAXIAL LAYER GROWTH APPARATUS INCLUDING THE SAME

(71) Applicant: SK SILTRON CO., LTD., Gumi-si (KR)

(72) Inventors: Yong Jin KIM, Gumi-si (KR); Dong Ho KANG, Gumi-si (KR)

(21) Appl. No.: 19/014,581

(22) Filed: Jan. 9, 2025

(30) Foreign Application Priority Data
Feb. 19, 2024 (KR) 10-2024-0023762

(51) Int. Cl. H01L 21/687; C23C 16/458; C23C 16/46; C30B 25/12; C30B 25/16

(52) U.S. Cl. CPC H01L 21/68785; C23C 16/4583; C23C 16/46; C30B 25/12; C30B 25/16

(57) ABSTRACT

Disclosed is a susceptor including a susceptor including a body including a bottom surface configured to support a wafer and a side wall configured to extend upward from a perimeter of the bottom surface, and a temperature control member disposed inside the side wall adjacent to the side wall at an edge of the bottom surface.

### CROSS-REFERENCE TO RELATED PATENT APPLICATIONS

This application claims the benefit of Korean Patent Application No. 10-2024-0023762, filed on Feb. 19, 2024, which is hereby incorporated by reference as if fully set forth herein.

### BACKGROUND OF THE INVENTION

### Field of the Invention

The present disclosure relates to a susceptor and an epitaxial layer growth apparatus including the same, and more particularly, to a susceptor and an epitaxial layer growth apparatus including the same that control heat supplied to the edge of a wafer so that an epitaxial layer is grown with a uniform thickness over the entire area of the wafer.

### Discussion of the Related Art

An epitaxial wafer is a wafer obtained by growing a thin single crystal layer on a polished wafer used as a substrate by chemical vapor deposition (CVD) in a chamber heated to a high temperature of 1,100° C. or higher.

Since the epitaxial wafer is manufactured by growing an epitaxial layer on a silicon wafer, an epitaxial layer and an epitaxial wafer with a desired resistivity may be manufactured by controlling the doping amount of impurities in the epitaxial layer.

Epitaxial wafers have high gathering capability, low latch-up characteristics, and slip resistance at a high temperature, and thus, they are recently widely used as wafers for manufacturing not only MOS devices but also LSI devices.

As quality items required for these epitaxial wafers, items for the surface of the epitaxial wafer including a substrate and an epitaxial layer include flatness, and a particle contamination degree, and items for the epitaxial layer itself include thickness uniformity, resistivity, and resistivity uniformity of the epitaxial layer, metal contamination, stacking faults, and slip dislocation.

The thickness uniformity or flatness of the epitaxial layer has a great influence on the photolithography process, the chemical mechanical polishing (CMP) process, and the bonding process for silicon on insulator (SOI) wafers during a process of manufacturing semiconductor devices on an epitaxial wafer. Particularly, since edge roll-off (ERO), in which the edge of a wafer is rolled up or down, has a great influence on defocus in the photolithography process, polishing uniformity in the CMP process, and bonding failure in the SOI bonding process, and as the diameter of the wafer increases to 300 mm or more, the flatness of the edge of the wafer is becoming increasingly important as a quality item of epitaxial wafers, it is necessary to find out the cause of a phenomenon in which the flatness of the edge of the epitaxial wafer is distorted.

### SUMMARY OF THE INVENTION

Accordingly, the present disclosure is directed to a susceptor and an epitaxial layer growth apparatus including the same that substantially obviate one or more problems due to limitations and disadvantages of the related art.

An object of the present disclosure is to improve the flatness of an epitaxial wafer by growing an epitaxial layer on a wafer to have a uniform thickness.

Additional advantages, objects, and features of the disclosure will be set forth in part in the description which follows and in part will become apparent to those having ordinary skill in the art upon examination of the following or may be learned from practice of the disclosure. The objectives and other advantages of the disclosure may be realized and attained by the structure particularly pointed out in the written description and claims hereof as well as the appended drawings.

To achieve these objects and other advantages and in accordance with the purpose of the disclosure, as embodied and broadly described herein, a susceptor includes a body including a bottom surface configured to support a wafer and a side wall configured to extend upward from a perimeter of the bottom surface, and a temperature control member disposed inside the side wall adjacent to the side wall at an edge of the bottom surface.

The temperature control member may be formed as the same material as the body.

The temperature control member may be provided integrally with the body.

A width of the temperature control member in a horizontal direction may be variable.

The temperature control member may have a plurality of first points having a maximum width in the horizontal direction and a plurality of second points having a minimum width in the horizontal direction, and the first points and the second points may be alternately arranged in a rotating direction of the susceptor about a center thereof.

A number of the first points and the number of the second points may be four, the first points may be arranged symmetrically with respect to the center of the susceptor, and the second points may be arranged symmetrically with respect to the center of the susceptor.

The temperature control member may include a first part having an annular shape and supported by the bottom surface of the body and a second part configured to extend from an upper portion of the first part toward the side wall of the body.

A height of the bottom surface of the body in an area where the first part is disposed may be lower than a height of the bottom surface of the body in an area where the wafer is disposed.

A height of an upper surface of the second part of the temperature control member may be equal to or higher than a height of an upper surface of the wafer.

The height of the upper surface of the second part of the temperature control member may be lower than the height of the upper surface of the wafer.

The temperature control member may have an annular shape having an inverted triangular cross-section in a direction from a center of the susceptor toward an outside, and a vertex of the inverted triangular cross-section may be disposed in a direction toward the center of the susceptor.

A height of a base of the inverted triangular cross-section may be equal to or higher than a height of the wafer.

The height of the base of the inverted triangular cross-section may be lower than the height of the wafer.

The wafer may be a silicon wafer, the first points may face regions of the wafer where a crystal orientation of silicon is <100>, and the second points may face regions of the wafer where the crystal orientation of silicon is <110>.

In another aspect of the present disclosure, an epitaxial layer growth apparatus includes a chamber, a susceptor configured to provide a region where a wafer is placed within the chamber, a pin provided under the susceptor to support the wafer, and a reaction gas supply unit configured to supply reaction gas to grow an epitaxial layer on a surface of the wafer to an upper surface of the wafer, wherein the susceptor includes a body including a bottom surface configured to support the wafer and a side wall configured to extend upward from a perimeter of the bottom surface, and a temperature control member disposed inside the side wall adjacent to the side wall at an edge of the bottom surface.

### BRIEF DESCRIPTION OF THE DRAWINGS

The accompanying drawings, which are included to provide a further understanding of the disclosure and are incorporated in and constitute a part of this application, illustrate embodiment(s) of the disclosure and together with the description serve to explain the principle of the disclosure. In the drawings:

FIG. 1 shows an epitaxial layer growth apparatus according to one embodiment of the present disclosure;

FIG. 2 shows crystal orientations of a silicon wafer;

FIG. 3 is a thickness profile of an epitaxial layer grown in each direction of the silicon wafer in FIG. 2;

FIGS. 4A and 4B show comparative examples of a susceptor of FIG. 1;

FIGS. 5A to 5C show embodiments of the susceptor of FIG. 1; and

FIG. 6 is a plan view of the susceptors of FIGS. 5A to 5C.

### DETAILED DESCRIPTION OF THE INVENTION

Hereinafter, embodiments will be described in detail so as to concretely describe the present disclosure and to aid in understanding of the present disclosure, with reference to the accompanying drawings.

However, the embodiments of the present disclosure may be variously modified and be implemented in various different forms, and it will be understood that the scope of the present disclosure should not be interpreted as being limited to the embodiments set forth herein. The embodiments of the present disclosure are provided to make the description of the present disclosure thorough and to fully convey the scope of the present disclosure to those skilled in the art.

Further, relative terms, such as “first,” “second,” “below,” “lower,” “above,” “upper,” and the like when used herein, do not necessarily require or imply any physical or logical relationship between substances or elements indicated by the terms or a sequence or order thereof, and may be used only to distinguish one substance or element from another substance or element.

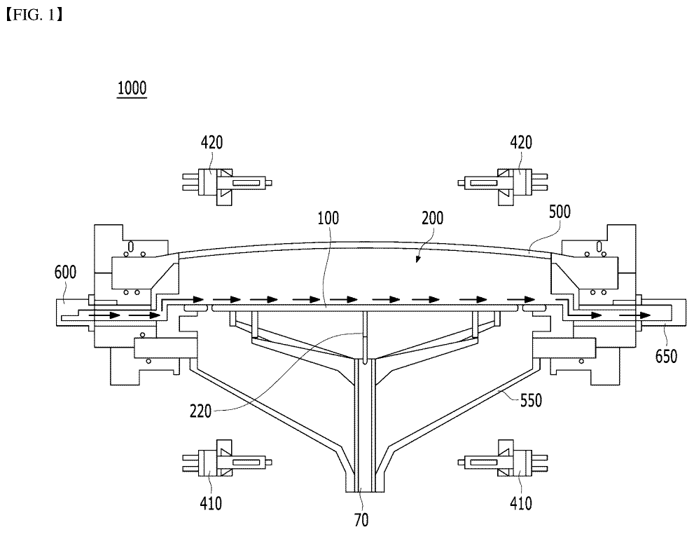

FIG. 1 shows an epitaxial layer growth apparatus according to one embodiment of the present disclosure.

Referring to FIG. 1, an epitaxial layer growth apparatus 1000 according to this embodiment may include a chamber 200 having an internal space, a support pin 220 located within the chamber 200 to be rotatable, and a susceptor 100 disposed on the support pin 220.

A wafer may be placed on the susceptor 100 to form an epitaxial layer on the wafer. The wafer may include, for example, a silicon wafer, a silicon carbide wafer, or the like. The wafer may undergo planar surface orientation, and may be a wafer whose upper and lower surfaces are mirror-polished.

The wafer may be placed on the susceptor 100 to form the epitaxial layer on the wafer. The wafer may include any one of wafers having various compositions, for example, a silicon (Si) wafer, a silicon carbide (SiC) wafer, a sapphire (Si₂O₃) wafer, or a gallium nitride (GaN) wafer, and the same is applied to embodiments and related drawings which will be described below. The wafer may undergo planar surface orientation, and may be a wafer whose upper and lower surfaces are mirror-polished.

The epitaxial layer growth apparatus 1000 according to this embodiment may include an upper dome 500 and a lower dome 550. The upper dome 500 and the lower dome 550 may include a light transmitting material, such as high-purity quartz, that transmits light to radiantly heat the wafer.

The epitaxial layer growth apparatus 1000 according to this embodiment may include heating members. The heating members may include first heating members 410 at the bottom and second heating members 420 at the top.

The first and second heating members 410 and 420 may radiantly heat the susceptor 100 and the wafer placed on the susceptor 100.

In addition, the epitaxial layer growth apparatus 1000 according to this embodiment may include a reaction gas supply unit 600 and a reaction gas discharge unit 650. For example, the reaction gas supply unit 600 and the reaction gas discharge unit 650 may be installed on both sides of the susceptor 100. The reaction gas supply unit 600 and the reaction gas discharge unit 650 may be installed to face each other with the susceptor 100 interposed therebetween. Hydrogen gas, carrier gas for epitaxial growth, etc. injected from the reaction gas supply unit 600 may pass through the susceptor 100 and be discharged through the reaction gas discharge unit 650.

In addition, the epitaxial layer growth apparatus 1000 may include a rotation shaft 70. The rotation shaft 70 may be connected to the susceptor 100 through the support pin 220. The susceptor 100 may also be rotated by rotation of the rotation shaft 70.

In the epitaxial layer growth apparatus 1000 according to this embodiment, the susceptor 100 includes a body and a temperature control member, which will be described later.

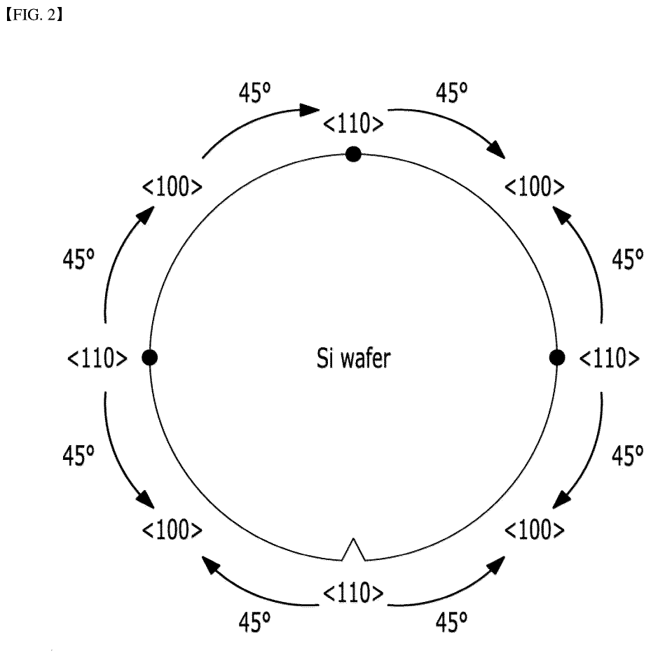

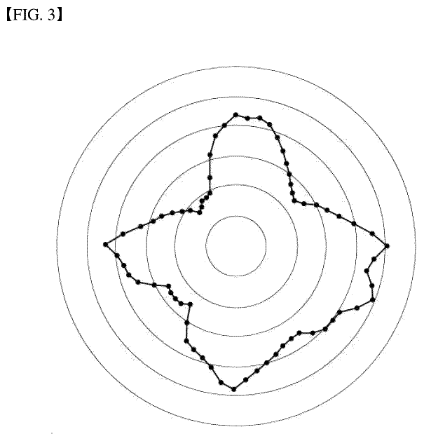

FIG. 2 shows crystal orientations of a silicon wafer, and FIG. 3 is a thickness profile of an epitaxial layer grown in each direction of the silicon wafer in FIG. 2.

The silicon wafer (Si wafer) of FIG. 2 may have a diameter of 300 mm, but is not limited thereto. The crystal orientation <110> of the silicon wafer appears at the 12 o'clock, 3 o'clock, 6 o'clock, and 9 o'clock directions, and the crystal orientation <100> appears at 450 from the positions of the crystal orientation <110>.

When the epitaxial layer is grown on the silicon wafer using a conventional epitaxial layer growth apparatus by a deposition method or the like, it may be seen that the epitaxial layer in the crystal orientation <110> is grown thicker than the epitaxial layer in the crystal orientation <100>, as shown in FIG. 3.

It is expected that such a deviation in the thickness of the epitaxial layer is caused by the temperature distribution on the susceptor on which the silicon wafer is placed, and the growth rate of the epitaxial layer is generally proportional to a growth temperature. Therefore, the more heat is supplied to the susceptor, the higher the temperature of the silicon wafer may be, and thus the thicker the epitaxial layer may be.

In the epitaxial layer growth apparatus 1000 of FIG. 1, it is necessary to control the amount of heat from the first and second heating members 410 and 420 that is supplied to the silicon wafer through the susceptor 100 or directly supplied to the silicon wafer, or to control the amount of heat discharged to the outside.

Heat may be transferred from the susceptor 100 or the bulk region of the silicon wafer to the front surface of the silicon wafer by conduction, and the capacity of heat that is conducted may be obtained by Mathematical Expression 1 below.

$$Q = - k A ( Δ T / Δ x ) \qquad < Mathematical Expression 1 >$$

Here, Q is the capacity of heat that is conducted, k(w/m·K) is thermal conductivity, A is the contact cross-sectional area of a substrate, and (ΔT/Δx) is a temperature gradient, i.e., a temperature change depending on a distance change.

In addition to this change in the capacity of heat that is conducted, it is necessary to control the capacity of heat that is discharged to the outside.

Therefore, the silicon wafer has a high growth rate of the epitaxial layer in the crystal orientation <110>, and therefore, a thickness deviation of the epitaxial layer as shown in FIG. 3 may occur, and accordingly, the temperature control member, which will be described below, may be provided in the susceptor 100 to control the distribution of heat supplied to the susceptor 100 to control the temperature distribution of the silicon wafer, thereby being capable of uniformly controlling the thickness distribution of the grown epitaxial layer.

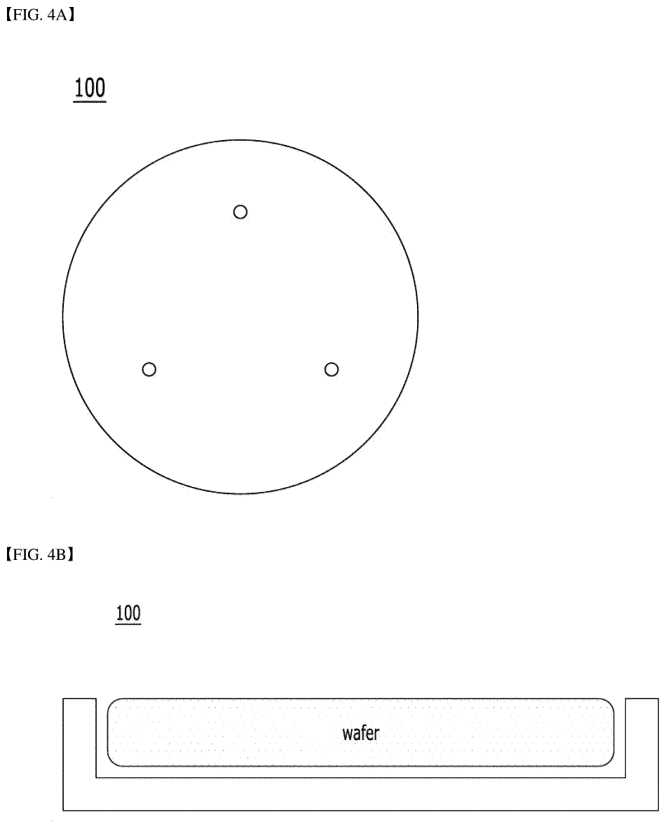

FIGS. 4A and 4B show comparative examples of the susceptor of FIG. 1.

As shown in FIG. 4A, holes are formed in the susceptor 100 so that the above-described support pin may support a wafer, and as shown in FIG. 4B, the susceptor 100 may include a bottom surface that supports a wafer and a side wall around the bottom surface. Here, the wafer may be a silicon wafer or a silicon carbide wafer.

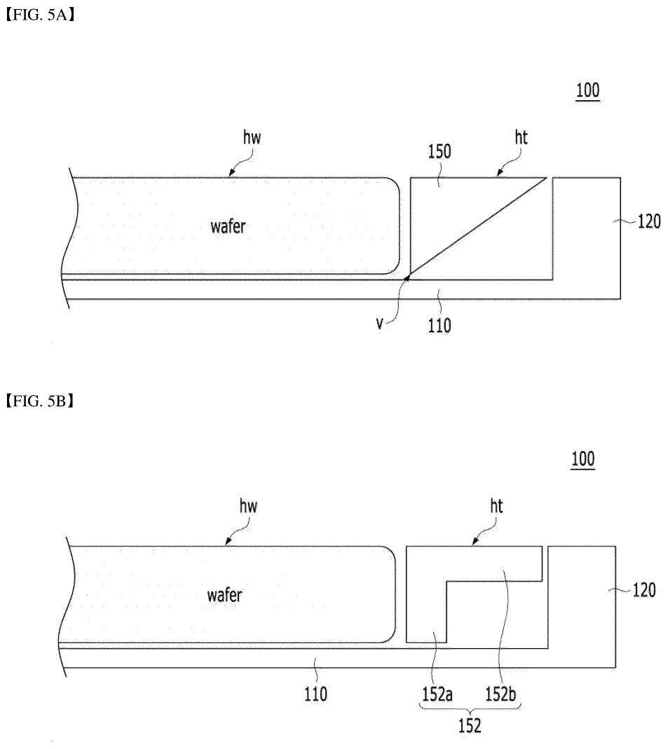

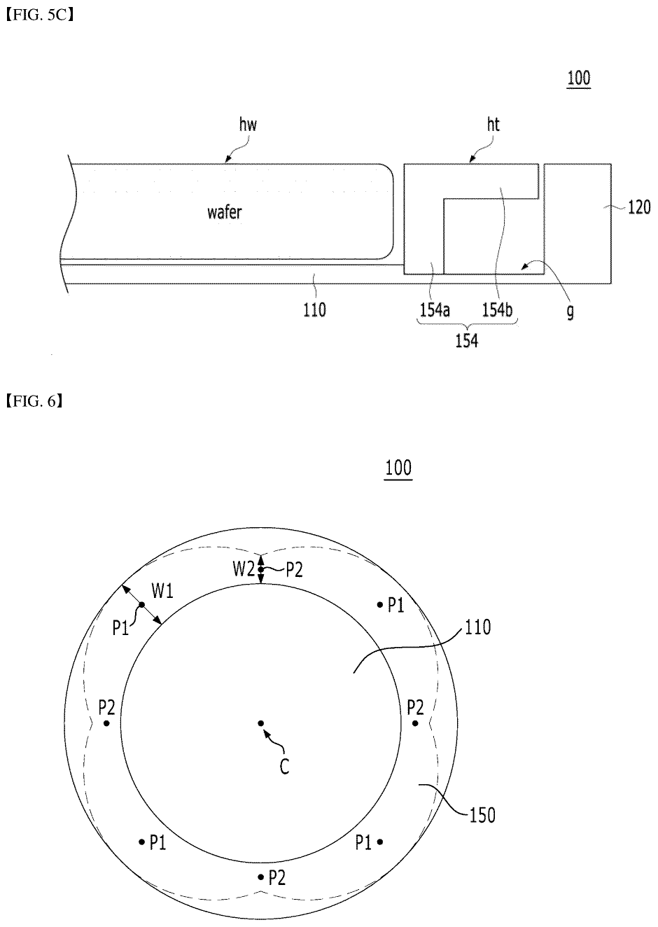

FIGS. 5A to 5C show embodiments of the susceptor of FIG. 1, and FIG. 6 is a plan view of the susceptors of FIGS. 5A to 5C. Hereinafter, the embodiments of the susceptor according to the present disclosure will be described with reference to FIGS. 5A to 6.

As shown in FIG. 6, the temperature control member may be provided in an annular shape surrounding an area where a wafer is disposed, and may thus be referred as a temperature control ring.

The temperature control member may be formed as the same material as the body of the susceptor 100, and although the body and the temperature control member are illustrated separately in FIGS. 5A to 5C, the body and the temperature control member may be provided as one unit. The temperature control member may be formed of a carbon-based material, such as silicon carbide (SiC) or graphite.

The susceptor 100 according to the embodiment illustrated in FIG. 5A may include a body including a bottom surface 110 that supports a wafer and a side wall 120 that extends upward from the perimeter of the bottom surface 110, and a temperature control member 150 disposed inside the side wall 120 adjacent to the side wall 120 at the edge of the bottom surface 110.

The temperature control member 150 has an inverted triangular cross-section in a direction from the center of the susceptor 100 toward the outside, and more specifically, the inverted triangular cross-section has a shape in which a right-angled triangle is placed upside down, and a vertex of the inverted triangular cross-section is disposed in a direction toward the center of the susceptor 100 rather than in a direction toward the edge of the susceptor 100.

In addition, in the above-described inverted triangular cross-section of the temperature control member 150, a base of the inverted triangular cross-section is placed at the top, and the height ht of the base may be equal to or higher than the height hw of the upper surface of the wafer. This height distribution may allow the temperature control member 150 to prevent heat of the wafer, particularly near the edge of the wafer, from being discharged outward.

In FIG. 5A, if the height ht of the base of the temperature control member 150 is provided to be equal to or higher than the height hw of the upper surface of the wafer, the temperature control member 150 becomes thicker and heat capacity may increase, and on the other hand, if the height ht of the base of the temperature control member 150 is provided to be lower than the height hw of the upper surface of the wafer, the temperature control member 150 becomes thinner and heat capacity may decrease, and accordingly, the temperature may be controlled depending on the crystal orientation of the wafer and thus the thickness of an epitaxial layer to be grown may be controlled. That is, the heat capacity may be decreased in regions having the crystal orientation <110> and the heat capacity may be increased in regions having the crystal orientation <100>, thereby being capable of controlling the thickness of the epitaxial layer to be grown.

In the embodiment illustrated in FIG. 5B, the susceptor 100 may be the same as the susceptor 100 in the embodiment illustrated in FIG. 5A, but may have a temperature control member 152 provided in a different shape. The temperature control member 152 may be disposed inside the side wall 120 adjacent to the side wall 120 at the edge of the bottom surface 110.

In addition, the temperature control member 152 may have an overall annular shape, but the cross-section of the temperature control member 152 in the direction from the center of the susceptor 100 toward the outside may include a first part 152a that is supported by the bottom surface 110 of the body and a second part 152b that extends from the upper portion of the first part 152a toward the side wall 120 of the body, and may thus have an approximately inverted L shape.

Here, the height ht of the upper surface of the second part 152b of the temperature control member 152 may be equal to or higher than the height hw of the upper surface of the wafer.

In FIG. 5B, if the height ht of the upper surface of the temperature control member 152 is provided to be equal to or higher than the height hw of the upper surface of the wafer, the temperature control member 152 becomes thicker and heat capacity may increase, and on the other hand, if the height ht of the upper surface of the temperature control member 152 is provided to be lower than the height hw of the upper surface of the wafer, the temperature control member 152 becomes thinner and heat capacity may decrease, and accordingly, the temperature may be controlled by varying the thickness of the temperature control member 152 depending on the crystal orientation of the wafer and thus the thickness of an epitaxial layer to be grown may be controlled. That is, the heat capacity may be decreased in regions having the crystal orientation <110> and the heat capacity may be increased in regions having the crystal orientation <100>, thereby being capable of controlling the thickness of the epitaxial layer to be grown.

The embodiment illustrated in FIG. 5C is the same as the embodiment illustrated in FIG. 5B, except that a groove g is formed in the bottom surface 110 forming the body of the susceptor 100. That is, the height of the bottom surface 110 of the body provided with the above-described groove g in an area where a first part 154a of a temperature control member 154 is disposed may be lower than the height of the bottom surface 110 of the body in an area where a wafer is disposed.

Due to the above-described groove g, heat may be prevented from being discharged in the edge direction even in an area in which the lower surface of the temperature control member 154 is lower than the lower surface of the wafer, thereby being capable of increasing the amount of heat supplied to the wafer.

FIG. 6 illustrates that a center C is provided on the bottom surface 110 of the susceptor 100 and the temperature control member 150 is provided in an annular shape surrounding the center C in some areas of the side wall 120.

The temperature control member 150 may have a plurality of first points P1 having a maximum width W1 in the horizontal direction and a plurality of second points P2 having a minimum width W2 in the horizontal direction, and the first points P1 and the second points P2 may be alternately arranged in the rotating direction of the susceptor 100 about the center C thereof. In addition, the first points P1 and the second points P2 may be arranged to face the points of the wafer having the crystal orientation <100> and the points of the wafer having the crystal orientation <110>, as shown in FIG. 2, respectively.

Specifically, in FIG. 6, four first points P1 and four second points P2 may be provided, the first points P1 may be arranged symmetrically with respect to the center C of the susceptor 100, and the second points P2 may be arranged symmetrically with respect to the center C of the susceptor 100.

The susceptor and the epitaxial layer growth apparatus including the same according to the present disclosure may be provided with the temperature control member around the area of the susceptor where the wafer is disposed to reduce the amount of heat emitted between the bottom surface of the susceptor and the edge of the wafer, and particularly in the case of a silicon wafer, the temperature control member may be provided to have a greater width in the horizontal direction in areas facing the areas of the wafer having the crystal orientation <100> to increase heat retention in the corresponding areas, and may thus promote growth of the epitaxial layer on the areas of the wafer having the crystal orientation <100> where the epitaxial layer may be grown relatively thinly to improve the flatness of the epitaxial layer through uniform growth of the epitaxial layer on the silicon wafer.

As is apparent from the above description, a susceptor and an epitaxial layer growth apparatus including the same according to embodiments of the present disclosure is provided with a temperature control member around an area of the susceptor where a wafer is disposed and may thus reduce the amount of heat emitted between the bottom surface of the susceptor and the edge of the wafer, and particularly in the case of a silicon wafer, the temperature control member is provided to have a greater width in the horizontal direction in areas facing the areas of the wafer having the crystal orientation <100> to increase heat retention in the corresponding areas, and may thus promote growth of the epitaxial layer on the areas having the crystal orientation <100> where the epitaxial layer may be grown relatively thinly, thereby allowing the epitaxial layer to be grown uniformly in thickness on the silicon wafer.

While the embodiments of the present disclosure have been explained in detail with reference to the accompanying drawings, the present disclosure is not limited to these embodiments, and it will be apparent to those skilled in the art that various modifications and variations can be made in the present disclosure without departing from the spirit or scope of the disclosure. Therefore, the embodiments disclosed in the present disclosure are for the purpose of describing the disclosure only and are not intended to limit the scope of the disclosure, and the scope of the disclosure is not limited by the embodiments. Accordingly, it will be understood that the above-described embodiments are only exemplary and are not intended to limit the present disclosure. The scope of the present disclosure is defined not by the detailed description, but by the claims and their equivalents, and all variations within the scope of the claims and their equivalents are to be construed as being included in the present disclosure.

What is claimed is:

1. A susceptor comprising:
a body comprising a bottom surface configured to support a wafer and a side wall configured to extend upward from a perimeter of the bottom surface; and
a temperature control member disposed inside the side wall adjacent to the side wall at an edge of the bottom surface.

2. The susceptor according to claim 1, wherein the temperature control member is formed as the same material as the body.

3. The susceptor according to claim 1, wherein the temperature control member is provided integrally with the body.

4. The susceptor according to claim 1, wherein a width of the temperature control member in a horizontal direction is variable.

5. The susceptor according to claim 4, wherein the temperature control member has a plurality of first points having a maximum width in the horizontal direction and a plurality of second points having a minimum width in the horizontal direction, and the first points and the second points are alternately arranged in a rotating direction of the susceptor about a center thereof.

6. The susceptor according to claim 5, wherein a number of the first points and the number of the second points are four, the first points are arranged symmetrically with respect to the center of the susceptor, and the second points are arranged symmetrically with respect to the center of the susceptor.

7. The susceptor according to claim 1, wherein the temperature control member comprises a first part having an annular shape and supported by the bottom surface of the body and a second part configured to extend from an upper portion of the first part toward the side wall of the body.

8. The susceptor according to claim 7, wherein a height of the bottom surface of the body in an area where the first part is disposed is lower than a height of the bottom surface of the body in an area where the wafer is disposed.

9. The susceptor according to claim 7, wherein a height of an upper surface of the second part of the temperature control member is equal to or higher than a height of an upper surface of the wafer.

10. The susceptor according to claim 7, wherein a height of an upper surface of the second part of the temperature control member is lower than a height of an upper surface of the wafer.

11. The susceptor according to claim 1, wherein:
the temperature control member has an annular shape having an inverted triangular cross-section in a direction from a center of the susceptor toward an outside; and
a vertex of the inverted triangular cross-section is disposed in a direction toward the center of the susceptor.

12. The susceptor according to claim 11, wherein a height of a base of the inverted triangular cross-section is equal to or higher than a height of the wafer.

13. The susceptor according to claim 11, wherein a height of a base of the inverted triangular cross-section is lower than a height of the wafer.

14. The susceptor according to claim 5, wherein the wafer is a silicon wafer, the first points face regions of the wafer where a crystal orientation of silicon is <100>, and the second points face regions of the wafer where the crystal orientation of silicon is <110>.

15. An epitaxial layer growth apparatus comprising:
a chamber;
a susceptor configured to provide a region where a wafer is placed within the chamber;
a pin provided under the susceptor to support the wafer; and
a reaction gas supply unit configured to supply reaction gas to grow an epitaxial layer on a surface of the wafer to an upper surface of the wafer,
wherein the susceptor comprises a body comprising a bottom surface configured to support the wafer and a side wall configured to extend upward from a perimeter of the bottom surface, and a temperature control member disposed inside the side wall adjacent to the side wall at an edge of the bottom surface.

16. The epitaxial layer growth apparatus according to claim 15, wherein the temperature control member is formed as the same material as the body, and is provided integrally with the body.

17. The epitaxial layer growth apparatus according to claim 16, wherein the temperature control member has a plurality of first points having a maximum width in a horizontal direction and a plurality of second points having a minimum width in the horizontal direction, and the first points and the second points are alternately arranged in a rotating direction of the susceptor about a center thereof.

18. The epitaxial layer growth apparatus according to claim 17, wherein a number of the first points and the number of the second points are four, the first points are arranged symmetrically with respect to the center of the susceptor, and the second points are arranged symmetrically with respect to the center of the susceptor.

19. The epitaxial layer growth apparatus according to claim 15, wherein the temperature control member comprises a first part having an annular shape and supported by the bottom surface of the body and a second part configured to extend from an upper portion of the first part toward the side wall of the body.

20. The epitaxial layer growth apparatus according to claim 15, wherein:
the temperature control member has an annular shape having an inverted triangular cross-section in a direction from a center of the susceptor toward an outside; and
a vertex of the inverted triangular cross-section is disposed in a direction toward the center of the susceptor.
